(19) United States
(12) Patent Application Publication
(10) Pub. No.: US 2024/0258812 A1
(43) Pub. Date: Aug. 1, 2024

(54) BATTERY PACK MAINTENANCE AND CHARGING

(71) Applicant: Medtronic, Inc., Minneapolis, MN (US)

(72) Inventors: Laura E. McCalla, Brossard (CA); Gregory D. Rise, Mound, MN (US); Joseph M. Galewski, Richfield, MN (US); Gordon O. Munns, Stacy, MN (US); Howell B. Schwartz, San Diego, CA (US)

(21) Appl. No.: 18/423,445

(22) Filed: Jan. 26, 2024

Related U.S. Application Data
(60) Provisional application No. 63/481,792, filed on Jan. 26, 2023.

(51) Int. Cl. H02J 7/00; G01R 31/36; H01M 10/6572

(52) U.S. Cl. CPC H02J 7/0071; G01R 31/3646; H01M 10/6572; H02J 7/0013; H02J 7/0048; H02J 7/0069; H02J 7/00302; H02J 7/00309

(57) ABSTRACT

Example systems and techniques are described herein for maintaining a rechargeable battery packs. An example battery management system includes processing circuitry coupled to memory and a plurality of battery connectors. The processing circuitry is configured to determine a first number of rechargeable battery packs removably coupled to a respective battery connector that comprise a respective charged battery and to determine a second number of rechargeable battery packs removably coupled to a respective battery connector that are in a storage mode. The processing circuitry is configured to determine that the first number meets the charged battery threshold and determine that the second number does not meet the storage mode threshold. The processing circuitry is configured to, based at least in part on the first number meeting the charged battery threshold and the second number not meeting the storage mode threshold, place a rechargeable battery pack in the storage mode.

### RELATED APPLICATIONS

This application claims the benefit of U.S. Provisional Application Ser. No. 63/481,792, filed Jan. 26, 2023, the entire contents of each of which are incorporated herein by reference.

### TECHNICAL FIELD

The disclosure relates to rechargeable batteries and, more particularly, to systems and techniques for maintaining and charging rechargeable batteries.

### BACKGROUND

Many devices, including ventilators, such as those used in hospitals, other medical devices, wireless power tools, vehicles, among others, utilize rechargeable batteries. Many times, these rechargeable batteries are included in rechargeable battery packs. A rechargeable battery pack may include circuitry, such as a battery management system (BMS), that may be used to monitor battery parameters of a battery, such as a state-of-charge (SOC) of the battery, a state-of-health (SOH) of the battery, or the like. The SOC of a battery may be an indication of how fully charged a battery may be. The SOH of a battery may be an indication of how healthy a battery may be and whether the battery should be replaced.

Many rechargeable battery packs may be removed from the device which the rechargeable battery pack is configured to power for recharging purposes. The rechargeable battery pack may be removably inserted into or otherwise coupled with a charging system to recharge a rechargeable battery within the rechargeable battery pack. For example, the charging system may couple the rechargeable battery pack to a power source to recharge the rechargeable battery pack. The rechargeable battery pack may be removed from the charging system, for example, after the rechargeable battery pack has been at least partially recharged and may be reintroduced to the device which the rechargeable battery pack is configured to power.

### SUMMARY

In some aspects, this disclosure is directed to systems for charging and maintaining rechargeable batteries, such rechargeable batteries within rechargeable battery packs that may be used, for example, to power medical equipment, such as ventilators, or other devices, and techniques for such systems to charge and maintain rechargeable batteries. The present disclosure describes a battery pack management system which is configured to manage a set of rechargeable battery packs, such as rechargeable battery packs for ventilators in a hospital, to properly maintain such battery packs and to attempt to ensure that enough charged battery packs are available for potential use. When battery packs are not in use in a device, most battery packs are kept coupled to or plugged into chargers. However, when battery packs are kept at the top of charge for an extended period of time, this can lead to reduced battery performance and in some cases, battery cell failure or even battery cell venting. Battery cell venting may include the release of internal battery pressure, such as through a hot effluent, which may impinge on adjacent cells and thereby trigger a thermal-runaway condition within the battery. Predictability of rechargeable battery performance may be highly desirable, particularly when a rechargeable battery is used in a medical device. As accurate determination of rechargeable battery parameters may require the battery reach a sufficient and suitable depth of discharge (DOD), it may be desirable to, as part of maintaining a battery, to, on occasion, at least partially discharge a rechargeable battery. This may be particularly desirable for determination of battery parameters that may be related to battery SOH. A DOD may be an amount of discharge a battery may have in comparison to a total charge. A DOD may be a corollary to an SOC. For example, when a battery is 75% charged, the SOC may be 75% and the DOD may be 25%. When a battery is 25% charged, the SOC may be 25% and the DOD may be 75%.

In one example, the disclosure is directed to a battery management system including: a plurality of battery connectors, each battery connector of the plurality of battery connectors configured to removably connect to a respective rechargeable battery pack and to removably couple the respective rechargeable battery pack with a power source; a memory configured to store a charged battery threshold and a storage mode threshold; and processing circuitry coupled to the memory and the plurality of battery connectors, the processing circuitry being configured to: determine a first number of rechargeable battery packs of a plurality of rechargeable battery packs removably coupled to a respective battery connector that comprise a respective charged battery; determine a second number of rechargeable battery packs of the plurality of rechargeable battery packs removably coupled to a respective battery connector that are in a storage mode; determine that the first number meets the charged battery threshold; determine that the second number does not meet the storage mode threshold; and based at least in part on the first number meeting the charged battery threshold and the second number not meeting the storage mode threshold, place a first rechargeable battery pack of the plurality of rechargeable battery packs removably coupled to a respective battery connector in the storage mode.

In another example, the disclosure is directed to a method of battery management including: determining a first number of rechargeable battery packs of a plurality of rechargeable battery packs removably coupled to a respective battery connector of a plurality of battery connectors of a battery management system that comprise a respective charged battery; determining a second number of rechargeable battery packs of the plurality of rechargeable battery packs removably coupled to a respective battery connector of the plurality of battery connectors of the battery management system that are in a storage mode; determining that the first number meets a charged battery threshold; determining that the second number does not meet a storage mode threshold; and based at least in part on the first number meeting the charged battery threshold and the second number not meeting the storage mode threshold, placing a first rechargeable battery pack of the plurality of rechargeable battery packs removably coupled to a respective battery connector of the plurality of battery connectors of the battery management system in the storage mode.

In another example, the disclosure is directed to a non-transitory storage medium comprising instructions that when executed by one or more processors cause the one or more processors to: determine a first number of rechargeable battery packs of a plurality of rechargeable battery packs removably coupled to a respective battery connector of a plurality of battery connectors of a battery management system that comprise a respective charged battery; determine a second number of rechargeable battery packs of the plurality of rechargeable battery packs removably coupled to a respective battery connector of the plurality of battery connectors of the battery management system that are in a storage mode; determine that the first number meets a charged battery threshold; determine that the second number does not meet a storage mode threshold; and based at least in part on the first number meeting the charged battery threshold and the second number not meeting the storage mode threshold, place a first rechargeable battery pack of the plurality of rechargeable battery packs removably coupled to a respective battery connector in the storage mode.

The details of one or more examples of the disclosure are set forth in the accompanying drawings and the description below. Other features, objects, and advantages of the disclosure will be apparent from the description and drawings, and from the claims.

### BRIEF DESCRIPTION OF DRAWINGS

FIG. 1 is a block diagram of an example rechargeable battery management system in accordance with one or more techniques of this disclosure.

FIG. 2 is a block diagram of an example rechargeable battery pack.

FIG. 3 is a flow diagram illustrating example rechargeable battery management techniques in accordance with this disclosure.

### DETAILED DESCRIPTION

A variety of devices may utilize rechargeable batteries as a power source for operational power. For example, ventilators, other medical devices, wireless power tools, vehicles, wearable devices, laptop computers, tablet computers, cellular phones or any other device may utilize rechargeable batteries to power their operations. Some devices use rechargeable battery packs that include a rechargeable battery. Rechargeable battery packs may be removeable from a device that the rechargeable battery pack is configured to power to be inserted into or otherwise coupled to a battery charging system for recharging the rechargeable battery pack.

A rechargeable battery management system according to the techniques of this disclosure may provide otherwise missing functions in traditional battery charging systems that may enable an extra layer of safety with high energy battery packs that are used in a variety of use cases, such as within a hospital or elsewhere. Leaving a battery connected to a charger for a long period of time may lead to an increased safety risk, an increased risk of sudden unexplained capacity depletion, or inaccurate runtimes that may not meet International Electrotechnical Commission (IEC) minimum alarm time requirements. By periodically maintaining and updating the state of health and key battery management system parameters on rechargeable battery packs, the techniques of this disclosure may reduce such risks.

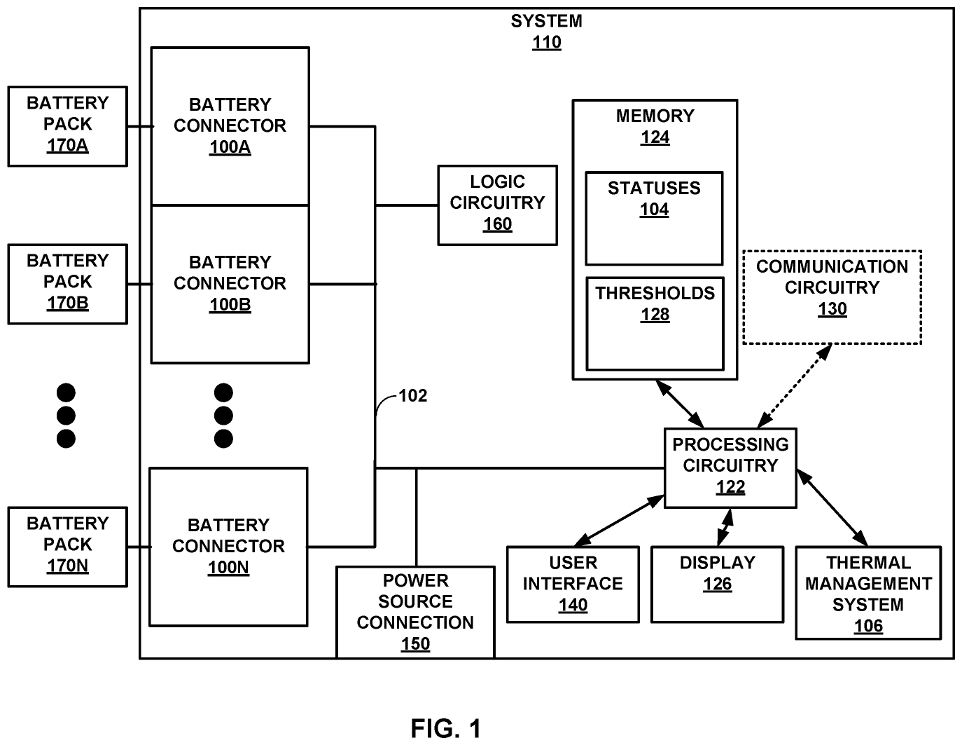

FIG. 1 is a block diagram of an example rechargeable battery management system in accordance with one or more techniques of this disclosure. FIG. 1 depicts system 110, which may be a rechargeable battery management system. System 110 may include a plurality of battery connectors (e.g., battery connector 100A - battery connector 100N, collectively referred to as battery connectors 100). Each of battery connectors 100 may be configured to connect to a rechargeable battery pack, such as battery packs 170A-170N (collectively battery packs 170). For example, each of battery connectors 100 may be configured to removably couple to a respective rechargeable battery pack. In some examples, battery connectors 100 may include slots, impressions, cradles or other form factors to receive rechargeable battery packs. In some examples, battery connectors 100 include connectors attached to cables or wires which may plug into rechargeable battery packs. Battery connectors 100 may be configured to provide both a data connection (e.g., for communication between battery packs 170 and processing circuitry 122) and a power connection (e.g., for charging batteries of battery packs 170). In some examples, battery connectors 100 may connect to battery packs 170 via wired connections (e.g., a wired data connection and/or a wired power connection). In some examples, battery connectors 100 may connect to battery packs 170 via wireless connections (e.g., a wireless data connection and/or a wireless power (e.g., inductive charging) connection). While N battery connectors and N battery packs are shown, it should be noted that, in some examples, fewer than N battery packs may be connected to system 110 via battery connectors 100 at a given time. For example, M battery packs may be connected to system 110 via M of battery connectors 100, where M<N.

Battery connectors 100 may be coupled to a bus 102 which may be configured to removably couple rechargeable battery packs to power source connection 150. For example, power source connection 150 may include a power cable which may be plugged into a power outlet. In some examples, power source connection may include a power source itself, such as a solar power source. Processing circuitry 122 may be configured to control bus 102 and/or power source connection 150 to apply or not apply charge from power source connection 150 to each of battery connectors 100 in a selectable manner. For example, processing circuitry 122 may control bus 102 to apply charge from power source connection 150 to battery connector 100A to charge a battery of battery pack 170A and to not apply charge from power source connection 150 to battery connector 100B so as to not charge a battery of battery pack 170B. While shown as a bus, bus 102 may take other forms, such as individually wired connections between power source connections 150 and each battery connector 100 and between processing circuity 122 and each battery connector 100. In such cases, processing circuitry 122 may control switches (e.g., of logic circuitry 160) coupled to the wired connections between power source connections 150 and each battery connector 100 to control whether a battery pack of battery packs 170 coupled to a battery connector of battery connectors 100 is being charged.

In some examples, system 110 may include a thermal management system 106. Thermal management system 106 may be configured to cool system 110 and/or any battery packs 170, or otherwise maintain a desired thermal environment for system 110 and/or any of battery packs 170. In some examples, thermal management system 106 may include at least one fan and/or at least one active cooling element. For example, an active cooling element of thermal management system 106 may include a Peltier element. In some examples, thermal management system 106 may include one or more temperature sensing elements, such as a thermistor, which may sense the temperature of system 110. Processing circuity 122 may monitor the temperature of system 110 and control the cooling operations of thermal management system 106 based on the monitored temperature. In some examples, a battery pack (e.g., battery pack 170A) of battery packs 170 may include a temperature sensing clement that may be configured to sense a temperature of battery pack 170A. In such examples, processing circuitry 122 may monitor the temperature of system battery pack 170A and control the cooling operations of thermal management system 106 based on the monitored temperature.

Processing circuitry 122 may be configured to charge battery packs 170 coupled to battery connectors 100, monitor the SOC and/or SOH of batteries of battery packs 170, perform maintenance on such batteries, or the like. For example, a rechargeable battery pack may include a battery management system, which processing circuitry 122 may interact with to determine the SOC, SOH or other parameters of the batteries of battery packs 170.

Processing circuitry 122 may be coupled to memory 124. Memory 124 may be configured to store various thresholds 128 discussed herein. Memory 124 may also be configured to store various statuses 104 discussed herein. Statuses 104 may include statuses, such a charging status; modes, such as a storage mode, a non-storage mode, etc .; parameters, such as battery parameters of battery packs 170; etc. In some examples, a storage mode may be a mode such as one which may be appropriate for and/or utilized for warehouse storage and/or common-carrier-transportation of a battery pack.

Processing circuitry 122 may also be coupled to a user interface 140 and/or display 126. In some examples, display 126 may form or be part of user interface 140. User interface 140 may include buttons, a keyboard, mouse, touchscreen, microphone and/or other devices facilitating the interaction of a user with system 110. For example, user interface 140 may permit a user to enter programming instructions to program processing circuitry 122 to perform certain tasks, such as to place one or more of battery packs 170 into a storage mode, remove a battery pack from the storage mode, perform specific tests on a battery pack or the like. In some examples, user interface 140 may be used by a user to change one or more of thresholds 128.

Display 126 may include an LCD display, an LED display, individual LEDs, or other display technology, configured to display information relating to system 110 or to any battery packs 170, such as a current mode of a battery of battery pack 170B, a status of the battery of battery pack 170B, such as an SOC, an SOH, or the like. In some examples, display 126 may include a touchscreen, enabling a user to input data, such as programming instructions to processing circuitry 122, via display 126.

Display 126 may be configured to display information relating to battery packs 170. For example, display 126 may display a simple, “at a glance” view of battery status of batteries of battery packs 170. Battery status may include, for example, ready to use, charging, storage mode, recommend replacement within a time period (e.g., three to six months), error or fault condition (e.g., recommend replacement), etc. In some examples, display 126 may display battery status through colored indicators, such as green—ready to use, flashing green—charging, grey—storage mode, yellow—recommended replacement within 3-6 months, red—error or fault condition—replace battery, or other color-coded indicators. In some examples, display 126 may be configured to display more detailed information regarding one or more batteries of battery packs 170 upon user request via user interface 140 and/or display 126 (in the case display 126 includes a touchscreen). Such more detailed information may include a present SOH of a battery, SOC of a battery, age of a battery, recommended time to replacement of a battery, etc.

In some examples, system 110 may optionally include communication circuitry 130. Communication circuitry 130 may include circuitry configured to communicate with one or more computing devices and/or one or more medical devices via a wireless, wired, or optical connection. In examples, where system 110 includes communication circuitry 130, a user may interact with system 110 via another device coupled via a network. For example, a user may input data and/or receive data from communication circuitry 130 via a user device (e.g., desktop computer, laptop computer, tablet computer, smartphone, or any other computing device capable of interacting with communication circuitry 130 or with such a network).

Processing circuitry 122 may include one or more general purpose microprocessors, digital signal processors (DSPs), application specific integrated circuits (ASICs), field programmable logic arrays (FPGAs), or other equivalent integrated or discrete logic circuitry. Accordingly, the term “processor” and “processing circuitry” as used herein may refer to any of the foregoing structure or any other structure suitable for implementation of the techniques described herein. Processing circuitry 122 may be configured to execute computer-readable instructions, which may be stored in memory 124, to provide various functionality to system 110 described herein.

Memory 124 may store such instructions as mentioned above. Memory 124 may include any volatile or non-volatile media, such as a random-access memory (RAM), read only memory (ROM), non-volatile RAM (NVRAM), electrically erasable programmable ROM (EEPROM), flash memory, and the like. Memory 124 may be a storage device or other non-transitory medium.

As mentioned above, memory 124 may store thresholds 128. Thresholds 128 may include a charged battery threshold and a storage mode threshold. The charged battery threshold may represent a minimum number (which may be less than a total number (N) of battery connectors 100) of battery packs 170 which system 110 may maintain in a charged state prior to placing a battery pack (e.g., battery pack 170A) into a storage mode, which is described later in this disclosure. For example, if the number of battery packs 170 that are not in a charged state does not meet the charged battery threshold, processing circuitry 122 may prevent battery pack 170A, that is not presently in a storage mode, from entering into the storage mode. In this manner, when possible, system 110 may maintain a minimum number of battery packs 170 in a charged state ready to be removed from battery connectors 100 to be deployed in and power other devices. By including a charged battery threshold, the techniques of this disclosure may ensure that at least a programmable number of battery packs include batteries that are charged (e.g., in a charged state as discussed herein) and available before putting a battery pack (which, in some examples, is not one of the batteries of the group of batteries meeting the charged battery threshold, while in other examples, the battery pack may be) in the storage mode.

The storage mode threshold may represent a maximum number of battery packs 170 that system 110 may permit to be in the storage mode at a given time. For example, it may be desirable to only have a limited number of battery packs 170 coupled to battery connectors 100 in the storage mode at a given time. For example, if system 110 is configured to manage 10 rechargeable battery packs at a time, it may be desirable to have no more than half (5) of those rechargeable battery packs in the storage mode at a given time. As discussed above, a user may set or change the charged battery threshold and/or the storage mode threshold. For example, if a user desires to have only 2 rechargeable battery packs of battery packs 170 in the storage mode at a time, the user may set or change the storage mode threshold to 2. For example, if the user desires to have 6 rechargeable battery packs of battery packs 170 in the charged state before placing a battery pack into the storage mode, the user may set or change the charged battery threshold to 6. By including a storage mode threshold, system 110 may ensure that no more than a programmable number of battery packs are in the storage mode at one time.

A charged state, as used herein, may be a fully charged state (the battery's relative SOC is 100%) or another charged state, which may be predetermined and/or programmable by a user. For example, rather than a charged state requiring a battery to have a SOC of 100%, the charged state may require a battery to have an SOC greater than (or equal to or greater than) a programmable level, such as 90%. This predetermined and/or programmable level may be referred to herein as a charged state threshold and may be stored in thresholds 128.

Prior to system 110 placing a battery pack, such as battery pack 170A, into storage mode, system 110 may perform maintenance on the battery pack. For example, processing circuitry 122 may discharge a battery of battery pack 170A to a sufficient depth of discharge, such as a predetermined depth of discharge in the range of 30%-100%, for example >37%. Processing circuitry 122 may then allow the battery of battery pack 170A to rest for a predetermined period of time, such a predetermined amount of time in the range of 5 minutes to 24 hours. Processing circuitry 122 may then charge the battery of battery pack 170A to a suitable and sufficient charge (e.g., a SOC of a predetermined amount, such as a predetermined SOC in the range of 1%-100%). Processing circuitry 122 may perform a logic check to determine if the battery should be entered into a storage mode. For example, processing circuitry 122 may determine whether it is desirable to place a battery in storage mode and may set a bit in memory 124 (e.g., in statuses 104) indicative of the battery being eligible to be placed in storage mode. For example, it may be desirable to only place a battery in storage mode if that battery is not being used frequently. As such, processing circuitry 122 may set the bit based on the battery being continuously coupled to a battery connector (e.g., of battery connectors 100) for at least a predetermined period of time or at least a predetermined number of charging top-up cycles, which may be indicative that the battery is not being used frequently.

If processing circuitry 122 determines that battery should be placed into storage mode, processing circuitry 122 may discharge the battery to an intermediate depth of charge, such as somewhere in the range of 30-70% SOC). In some examples, in storage mode, processing circuitry 122 performs this maintenance (described below) on the battery on a periodic basis. For example, processing circuitry 122 may perform maintenance on the battery every certain number of days. In some examples, processing circuitry 122 may perform maintenance on the battery if the SOC or SOH of the battery changes by a predetermined percentage or amount. In some examples, processing circuitry 122 may perform maintenance on the battery if the SOC or SOH of the battery changes by a predetermined percentage or amount within a predetermined time period. In some examples, a user may take a battery pack, such as battery pack 170A, out of storage mode, via user interface 140 and/or display 126, and enable processing circuitry 122 to charge the battery of battery pack 170A.

This disclosure discusses maintenance that may be performed on a battery pack while the battery pack is in the storage mode. Predictability of battery performance may be a high priority for many devices utilizing rechargeable batteries, such as medical devices. Batteries are typically monitored by an on-board (e.g., in battery packs 170) battery management system that may utilize an SOH algorithm which may be based on a full discharge capacity of the battery pack. Calendar fade (e.g., a fade in the capacity of the battery over time) may be critically dependent on a variety of conditions including battery cell temperature and other use conditions. Alternative, non-destructive, direct measurement techniques for determining SOH include Coulomb counting, cell impedance and electrochemical impedance spectroscopy, cycle number counting, calendar fade, and the like. Each of these SoH techniques may require a significantly complete (typically >37% depth of discharge) discharge of the battery pack.

Such a discharge limits the run-time of the battery powered device during this discharge. As such, it is desirable to avoid use of such a battery pack in a battery powered device while undergoing such maintenance. As such, display 126 may display which of battery packs 170 are in storage mode so as to enable a user to easily determine which of battery packs 170 are not suitable for use at a particular time.

For battery pack that is used for medical device monitoring and/or therapy, the battery within the battery pack is typically used when main power (e.g., from an outlet) to the device is interrupted, such as due to a power outage or a switch from between back-up generator power to/from utility company delivered power. A battery pack with such use conditions may be typically shallow cycled (e.g., charged after relatively shallow discharges) for long periods of time and seldom deeply discharged.

Processing circuitry 122 may perform maintenance on any battery packs (e.g., battery pack 170A) of battery packs 170 that are in storage mode. For example, processing circuitry 122 may evaluate a voltage response to a current-impulse of the battery of battery pack 170A. For example, processing circuitry 122 may employ Green's function, a Fast Fourier Transform (FFT) technique, and/or synchronous detection to address the power and energy evolution of the battery of battery pack 170A.

Green's function is the response of an inhomogeneous linear differential operator (L) to an impulse. Green's function G is the solution of the equation LG=d where d is Dirac's delta function (impulse). The solution of the initial value problem Ly−f is the convolution (G*f), where G is Green's function. Through superposition, processing circuitry 122 may determine the source as a sum of delta functions, and the solution as a sum of Green's functions by linearity of L.

Through an FFT technique, processing circuitry 122 can deconvolve the response of the battery to a basis of harmonics. In an example technique, processing circuitry 122 may use FFT to establish a square wave discharge/charge profile and deconvolve the response to the constituent odd harmonics and relative phases of the response.

To address potential low signal to noise ratio, processing circuitry 122 may usc synchronous detection (e.g., a lock-in amplifier) to suppress noise by mixing a signal with a replica of an un-modulated carrier. Processing circuitry 122 may modulate the response to a stimulus at some well-controlled/known frequency and mathematically extract the response by demodulation. With synchronous detection, processing circuitry 122 may essentially multiply a measured signal by a reference signal, such as a square wave. Through the synchronous detection techniques, processing circuitry 122 may remove most of the low frequency input noise.

In some examples, processing circuitry 122 may employ logic circuitry 160 to perform maintenance on, for example, battery pack 170A, using Green's function, FFT, and/or synchronous detection. In some examples, processing circuitry 122 may perform maintenance on battery pack 170A, without using logic circuitry 160. Processing circuitry 122 may determine a SOH of the battery based on one or more of these maintenance techniques. Based on the SOH of the battery, processing circuitry 122 may determine that a given battery pack should be replaced soon (e.g., within 3 to 6 months), is in an error or fault condition and should be replaced (e.g., not used to power a device), or that the battery pack is okay for use. In some examples, if the results of maintenance are relatively poor, processing circuitry 122 may attempt to resolve any determined issue and/or may report the results to a user, e.g., through display 126.

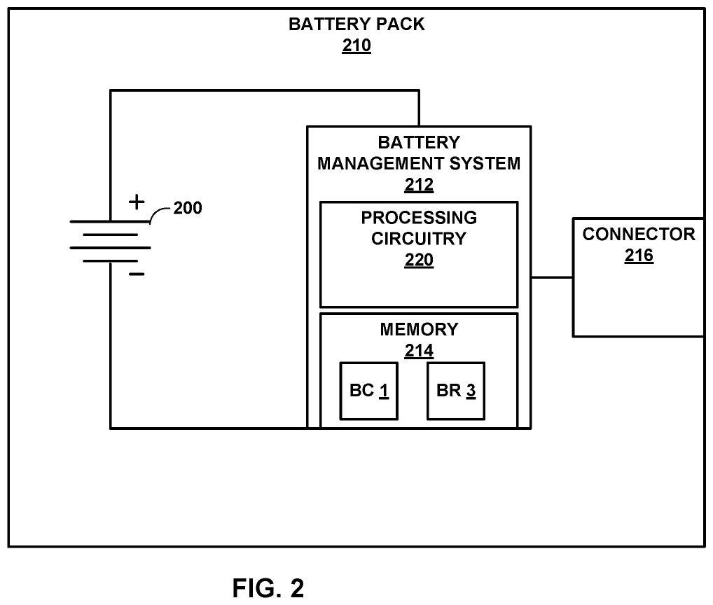

FIG. 2 is a block diagram of an example rechargeable battery pack. Battery pack 210, which may be a rechargeable battery pack, may be an example of each of, or any of, battery packs 170 of FIG. 1. Battery pack 210 may be configured to be inserted or otherwise coupled to a device (not shown) to provide power to that device. Example devices include medical equipment, such as ventilators; power tools; computing device, such as laptop computers, tablet computers, smartphones; vehicles; or other devices that may be powered by removeable battery packs.

Battery pack 210 may include battery 200. Battery 200 may be a rechargeable battery housed within battery pack 210. While not shown in FIG. 2, in some examples, battery pack 210 may contain a plurality of batteries, such as an active battery and a standby battery which may be utilized when the active battery is no longer able to supply sufficient power to a device.

Battery pack 210 may include a battery management system 212 which may be coupled to battery 200. Battery management system 212 may include processing circuitry 220 and memory 214. Processing circuitry 220 may include one or more general purpose microprocessors, digital signal processors (DSPs), application specific integrated circuits (ASICs), field programmable logic arrays (FPGAs), or other equivalent integrated or discrete logic circuitry. Processing circuitry 220 may be configured to execute computer-readable instructions, which may be stored in memory 214, to provide various functionality to battery pack 210 described herein. Memory 214 may store such instructions as mentioned above. Memory 214 may include any volatile or non-volatile media, such as a random-access memory (RAM), read only memory (ROM), non-volatile RAM (NVRAM), electrically erasable programmable ROM (EEPROM), flash memory, and the like. Memory 214 may be a storage device or other non-transitory medium.

Battery management system 212 may be configured to monitor, determine, and/or store parameters of battery 200, such as an SOC of battery 200, an SOH of battery 200, an age of battery 200, or other battery parameters of battery 200. In some examples, processing circuitry 220 may include one or more voltage sensors, impedance sensors, and/or Coulomb counters to monitor and/or determine battery parameters. Memory 214 may store parameters associated with battery 200. For example, memory 214 may store a battery capacity value, a battery resistance value, a state of charge, a relative state of charge, or the like.

Battery pack 210 may include connector 216 which may be coupled to battery management system 212 and/or battery 200. Connector 216 may be configured to be couple with a connector of a device to which battery pack 210 may provide power. Additionally, or alternatively, connector 216 may be configured to couple with one of battery connectors 100 of FIG. 1. When connector 216 is coupled to one of battery connectors 100, processing circuitry 122 may communicate with processing circuitry 220 to obtain battery parameters of battery 200 from memory 214 and/or to control processing circuitry 220 to perform maintenance on battery pack 210, determine battery parameters of battery 200 and/or obtain such battery parameters from processing circuitry 220. In some examples, processing circuitry 122 may determine certain battery parameters, such as SOC or SOH, rather than processing circuitry 220.

In some examples, a form factor of battery pack 210 may be such that the battery pack may be inserted into system 110 to couple connector 216 to one or battery connectors 100.

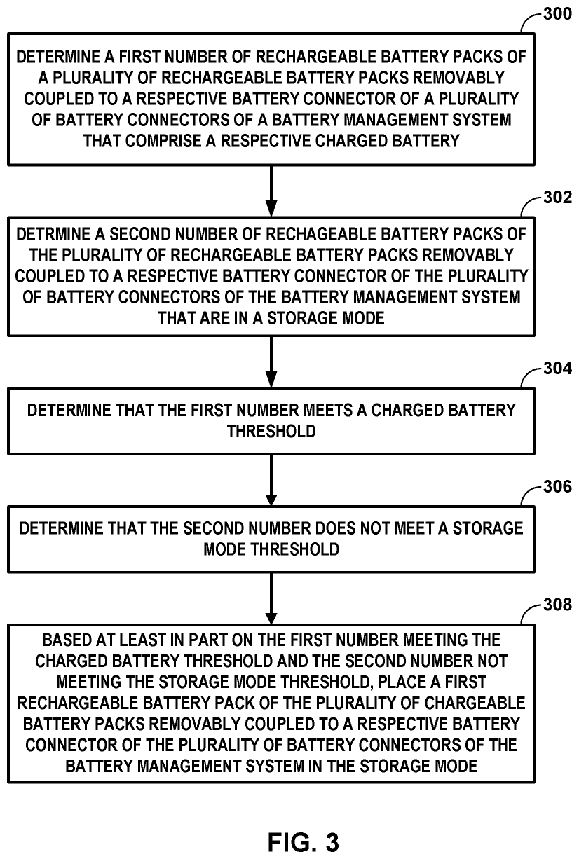

FIG. 3 is a flow diagram illustrating example battery maintenance and charging techniques of this disclosure. Processing circuitry 122 may determine a first number of rechargeable battery packs of a plurality of rechargeable battery packs removably coupled to a respective battery connector of a plurality of battery connectors of a battery management system that comprise a respective charged battery (300). For example, processing circuitry 122 may determine whether a respective battery of each battery pack of battery packs 170 is charged or is in a charged state. For example, processing circuitry 122 may determine whether a parameter of battery 200 meets the charged state threshold (e.g., 100% SOC, or other predetermined or programmed value). Processing circuitry 122 may count each rechargeable battery pack of battery packs 170 having a battery (e.g., battery 200) that is in the charged state to determine the first number.

Processing circuitry 122 may determine a second number of rechargeable battery packs of the plurality of battery packs removably coupled to a respective battery connector of the plurality of battery connectors of the battery management system that are in a storage mode (302). For example, processing circuitry 122 may store an indication of each rechargeable battery pack of battery packs 170 that is in the storage mode in statuses 104 of memory 124. Processing circuitry 122 may count each rechargeable battery pack in the storage mode to determine the second number.

Processing circuitry 122 may determine that the first number meets the charged battery threshold (304). For example, processing circuitry 122 may compare the first number to the charged battery threshold of thresholds 128 to determine whether the first number meets the charged battery threshold. For example, the first number may meet the charged battery threshold if the first number is equal to or greater than the charged battery threshold.

Processing circuitry 122 may determine that the second number does not meet the storage mode threshold (306). For example, processing circuitry 122 may compare the second number to the storage mode threshold of thresholds 128 to determine whether the second number does not meet the storage mode threshold. For example, the second number may not meet the storage mode threshold if the second number less than the storage mode threshold.

Processing circuitry 122, based at least in part on the first number meeting the charged battery threshold and the second number not meeting the storage mode threshold, may place a first rechargeable battery pack of the plurality of rechargeable battery packs removably coupled to a respective battery connector of the plurality of battery connectors of the battery management system in the storage mode (308).

In some examples, processing circuitry 122 may , prior to placing the first rechargeable battery pack in the storage mode, determine that rechargeable battery pack 210 has been removably coupled to the respective battery connector (e.g., of battery connectors 100) for at least a predetermined period of time or at least a predetermined number of charging top-up cycles. In some examples, the predetermined period of time may be 14 days or more (such as for batteries that may be used fairly regularly). In other examples, the predetermined period of time may be 30 days or more (such as for batteries that may be used less regularly). In some examples, the predetermined number of charging top-up cycles may be 30 or more. In some examples, based on rechargeable battery pack 210 being removably coupled to the respective battery connector for at least a first predetermined period of time or at least a predetermined number of top-up cycles, processing circuitry 122 may perform a maintenance check on rechargeable battery pack 210. In some examples, processing circuitry 122 placing rechargeable battery pack 210 in the storage mode is further based on results of the maintenance check.

In some examples, the maintenance check includes discharging battery 200 of rechargeable battery pack 210 to at least a predetermined depth of discharge; waiting a second predetermined period of time; charging battery 200 to at least a predetermined state of charge; determining, via a logic check, that rechargeable battery pack 210 should be placed into the storage mode.

In some examples, processing circuitry 122 is further configured to place a second rechargeable battery pack (which may be another example of rechargeable battery pack 210 or another rechargeable battery pack) in the storage mode based on at least one of user input or programmed parameters.

In some examples, as part of placing rechargeable battery pack 210 in the storage mode, processing circuitry 122 is configured to discharge battery 200 to an intermediate depth of discharge. In some examples, the intermediate depth of discharge is within the range of 30%-70%, inclusive.

In some examples, processing circuitry 122 is further configured to, based on rechargeable battery pack 210 being in the storage mode, perform performing periodic maintenance on battery 200. In some examples, performing periodic maintenance includes applying at least one of Green's function, a Fast Fourier Transform function, or synchronous detection. In some examples, processing circuitry 122 is further configured to remove rechargeable battery pack 210 from the storage mode and charge the battery 200 based on user input.

In some examples, processing circuitry 122 is further configured to output an indication for display that rechargeable battery pack 210 is in the storage mode. In some examples, processing circuitry 122 is further configured to output, for display, a battery status of battery 200.

In some examples, processing circuitry 122 is further configured to, in response to a user battery parameter request, output for display at least one battery parameter of battery 200.

In some examples, system 110 include thermal management system 106, wherein thermal management system includes at least one of an active cooling element or a fan. In some examples, the active cooling clement comprises a Peltier element.

This disclosure includes the following non-limiting examples.

Example 1. A battery management system comprising: a plurality of battery connectors, each battery connector of the plurality of battery connectors configured to removably connect to a respective rechargeable battery pack and to removably couple the respective rechargeable battery pack with a power source; a memory configured to store a charged battery threshold and a storage mode threshold; and processing circuitry coupled to the memory and the plurality of battery connectors, the processing circuitry being configured to: determine a first number of rechargeable battery packs of a plurality of rechargeable battery packs removably coupled to a respective battery connector that comprise a respective charged battery; determine a second number of rechargeable battery packs of the plurality of rechargeable battery packs removably coupled to a respective battery connector that are in a storage mode; determine that the first number meets the charged battery threshold; determine that the second number does not meet the storage mode threshold; and based at least in part on the first number meeting the charged battery threshold and the second number not meeting the storage mode threshold, place a first rechargeable battery pack of the plurality of rechargeable battery packs removably coupled to a respective battery connector in the storage mode.

Example 2. The battery management system of example 1, wherein the processing circuitry is further configured to: prior to placing the first rechargeable battery pack in the storage mode, determine that the first rechargeable battery pack has been removably coupled to the respective battery connector for at least a predetermined period of time or at least a predetermined number of charging top-up cycles; and based on the first rechargeable battery pack being removably coupled to the respective battery connector for at least a first predetermined period of time or at least a predetermined number of top-up cycles, perform a maintenance check on the first rechargeable battery pack, wherein placing the first rechargeable battery pack in the storage mode is further based on results of the maintenance check.

Example 3. The battery management system of example 2, wherein the maintenance check comprises: discharging a battery of the first rechargeable battery pack to at least a predetermined depth of discharge; waiting a second predetermined period of time;

charging the battery to at least a predetermined state of charge; and determining, via a logic check, that the first rechargeable battery pack should be placed into the storage mode.

Example 4. The battery management system of any of examples 1-3, wherein the processing circuitry is further configured to place a second rechargeable battery pack of the plurality of rechargeable battery packs in the storage mode based on at least one of user input or programmed parameters.

Example 5. The battery management system of any of examples 1-4, wherein as part of placing the first rechargeable battery pack in the storage mode, the processing circuitry is configured to discharge the battery to an intermediate depth of discharge.

Example 6. The battery management system of example 5, wherein the intermediate depth of discharge is within the range of 30%-70%, inclusive.

Example 7. The battery management system of any of examples 1-6, wherein the processing circuitry is further configured to, based on the first rechargeable battery pack being in the storage mode, perform periodic maintenance on the battery.

Example 8. The battery management system of example 7, wherein performing periodic maintenance comprises applying at least one of Green's function, a Fast Fourier Transform function, or synchronous detection.

Example 9. The battery management system of any of examples 1-8, wherein the processing circuitry is further configured to remove the first rechargeable battery pack from the storage mode and charge the battery based on user input.

Example 10. The battery management system of any of examples 1-8, wherein the processing circuitry is further configured to output an indication for display that the first rechargeable battery pack is in the storage mode.

Example 11. The battery management system of any of examples 1-10, wherein the processing circuitry is further configured to output, for display, a battery status of the battery.

Example 12. The battery management system of any of examples 1-11, wherein the processing circuitry is further configured to, in response to a user battery parameter request, output for display at least one battery parameter of the battery.

Example 13. The battery management system of any of examples 1-12, further comprising a thermal management system, wherein the thermal management system comprises at least one of an active cooling element or a fan.

Example 14. The battery management system of example 13, wherein the active cooling clement comprises a Peltier element.

Example 15. A method of battery management comprising: determining a first number of rechargeable battery packs of a plurality of rechargeable battery packs removably coupled to a respective battery connector of a plurality of battery connectors of a battery management system that comprise a respective charged battery; determining a second number of rechargeable battery packs of the plurality of rechargeable battery packs removably coupled to a respective battery connector of the plurality of battery connectors of the battery management system that are in a storage mode; determining that the first number meets a charged battery threshold; determining that the second number does not meet a storage mode threshold; and based at least in part on the first number meeting the charged battery threshold and the second number not meeting the storage mode threshold, placing a first rechargeable battery pack of the plurality of rechargeable battery packs removably coupled to a respective battery connector of the plurality of battery connectors of the battery management system in the storage mode.

Example 16. The method of example 15, further comprising: prior to placing the first rechargeable battery pack in the storage mode, determining that the first rechargeable battery pack has been removably coupled to the respective battery connector for at least a first predetermined period of time or at least a predetermined number of charging top-up cycles; and based on the first rechargeable battery pack being removably coupled to the respective battery connector for at least a predetermined period of time or at least a predetermined number of top-up cycles, performing a maintenance check on the first rechargeable battery pack, wherein placing the first rechargeable battery pack in the storage mode is further based on results of the maintenance check.

Example 17. The method of example 16, wherein the maintenance check comprises: discharging a battery of the first rechargeable battery pack to at least a predetermined depth of discharge; waiting a second predetermined period of time; charging the battery to at least a predetermined state of charge; and determining, via a logic check, that the first rechargeable battery pack should be placed into the storage mode.

Example 18. The method of any of examples 15-17, wherein the method further comprises placing a second rechargeable battery pack of the plurality of rechargeable battery packs in the storage mode based on at least one of user input or programmed parameters.

Example 19. The method of any of examples 15-18, wherein placing the first rechargeable battery pack in the storage mode comprises discharging the battery to an intermediate depth of discharge.

Example 20. A non-transitory storage medium comprising instructions that when executed by one or more processors cause the one or more processors to: determine a first number of rechargeable battery packs of a plurality of rechargeable battery packs removably coupled to a respective battery connector of a plurality of battery connectors of a battery management system that comprise a respective charged battery; determine a second number of rechargeable battery packs of the plurality of rechargeable battery packs removably coupled to a respective battery connector of the plurality of battery connectors of the battery management system that are in a storage mode; determine that the first number meets a charged battery threshold; determine that the second number does not meet a storage mode threshold; and based at least in part on the first number meeting the charged battery threshold and the second number not meeting the storage mode threshold, place a first rechargeable battery pack of the plurality of rechargeable battery packs removably coupled to a respective battery connector in the storage mode.

Various examples have been described in the disclosure. These and other examples are within the scope of the following claims.

1. A battery management system comprising:
a plurality of battery connectors, each battery connector of the plurality of battery connectors configured to removably connect to a respective rechargeable battery pack and to removably couple the respective rechargeable battery pack with a power source;
a memory configured to store a charged battery threshold and a storage mode threshold; and
processing circuitry coupled to the memory and the plurality of battery connectors, the processing circuitry being configured to:
determine a first number of rechargeable battery packs of a plurality of rechargeable battery packs removably coupled to a respective battery connector that comprise a respective charged battery;
determine a second number of rechargeable battery packs of the plurality of rechargeable battery packs removably coupled to a respective battery connector that are in a storage mode;
determine that the first number meets the charged battery threshold;
determine that the second number does not meet the storage mode threshold; and
based at least in part on the first number meeting the charged battery threshold and the second number not meeting the storage mode threshold, place a first rechargeable battery pack of the plurality of rechargeable battery packs removably coupled to a respective battery connector in the storage mode.

2. The battery management system of claim 1, wherein the processing circuitry is further configured to:
prior to placing the first rechargeable battery pack in the storage mode, determine that the first rechargeable battery pack has been removably coupled to the respective battery connector for at least a predetermined period of time or at least a predetermined number of charging top-up cycles; and
based on the first rechargeable battery pack being removably coupled to the respective battery connector for at least a first predetermined period of time or at least a predetermined number of top-up cycles, perform a maintenance check on the first rechargeable battery pack,
wherein placing the first rechargeable battery pack in the storage mode is further based on results of the maintenance check.

3. The battery management system of claim 2, wherein the maintenance check comprises:
discharging a battery of the first rechargeable battery pack to at least a predetermined depth of discharge;
waiting a second predetermined period of time;
charging the battery to at least a predetermined state of charge; and
determining, via a logic check, that the first rechargeable battery pack should be placed into the storage mode.

4. The battery management system of claim 1, wherein the processing circuitry is further configured to place a second rechargeable battery pack of the plurality of rechargeable battery packs in the storage mode based on at least one of user input or programmed parameters.

5. The battery management system of claim 1, wherein as part of placing the first rechargeable battery pack in the storage mode, the processing circuitry is configured to discharge the battery to an intermediate depth of discharge.

6. The battery management system of claim 5, wherein the intermediate depth of discharge is within the range of 30%-70%, inclusive.

7. The battery management system of claim 1, wherein the processing circuitry is further configured to, based on the first rechargeable battery pack being in the storage mode, perform periodic maintenance on the battery.

8. The battery management system of claim 7, wherein performing periodic maintenance comprises applying at least one of Green's function, a Fast Fourier Transform function, or synchronous detection.

9. The battery management system of claim 1, wherein the processing circuitry is further configured to remove the first rechargeable battery pack from the storage mode and charge the battery based on user input.

10. The battery management system of claim 1, wherein the processing circuitry is further configured to output an indication for display that the first rechargeable battery pack is in the storage mode.

11. The battery management system of claim 1, wherein the processing circuitry is further configured to output, for display, a battery status of the battery.

12. The battery management system of claim 1, wherein the processing circuitry is further configured to, in response to a user battery parameter request, output for display at least one battery parameter of the battery.

13. The battery management system of claim 1, further comprising a thermal management system, wherein the thermal management system comprises at least one of an active cooling element or a fan.

14. The battery management system of claim 13, wherein the active cooling element comprises a Peltier element.

15. A method of battery management comprising:
determining a first number of rechargeable battery packs of a plurality of rechargeable battery packs removably coupled to a respective battery connector of a plurality of battery connectors of a battery management system that comprise a respective charged battery;
determining a second number of rechargeable battery packs of the plurality of rechargeable battery packs removably coupled to a respective battery connector of the plurality of battery connectors of the battery management system that are in a storage mode;
determining that the first number meets a charged battery threshold;
determining that the second number does not meet a storage mode threshold; and
based at least in part on the first number meeting the charged battery threshold and the second number not meeting the storage mode threshold, placing a first rechargeable battery pack of the plurality of rechargeable battery packs removably coupled to a respective battery connector of the plurality of battery connectors of the battery management system in the storage mode.

16. The method of claim 15, further comprising:
prior to placing the first rechargeable battery pack in the storage mode, determining that the first rechargeable battery pack has been removably coupled to the respective battery connector for at least a first predetermined period of time or at least a predetermined number of charging top-up cycles; and
based on the first rechargeable battery pack being removably coupled to the respective battery connector for at least a predetermined period of time or at least a predetermined number of top-up cycles, performing a maintenance check on the first rechargeable battery pack,
wherein placing the first rechargeable battery pack in the storage mode is further based on results of the maintenance check.

17. The method of claim 16, wherein the maintenance check comprises:
discharging a battery of the first rechargeable battery pack to at least a predetermined depth of discharge;
waiting a second predetermined period of time;
charging the battery to at least a predetermined state of charge; and
determining, via a logic check, that the first rechargeable battery pack should be placed into the storage mode.

18. The method of any of claim 15, wherein the method further comprises placing a second rechargeable battery pack of the plurality of rechargeable battery packs in the storage mode based on at least one of user input or programmed parameters.

19. The method of any of claim 15, wherein placing the first rechargeable battery pack in the storage mode comprises discharging the battery to an intermediate depth of discharge.

20. A non-transitory storage medium comprising instructions that when executed by one or more processors cause the one or more processors to:
determine a first number of rechargeable battery packs of a plurality of rechargeable battery packs removably coupled to a respective battery connector of a plurality of battery connectors of a battery management system that comprise a respective charged battery;
determine a second number of rechargeable battery packs of the plurality of rechargeable battery packs removably coupled to a respective battery connector of the plurality of battery connectors of the battery management system that are in a storage mode;
determine that the first number meets a charged battery threshold;
determine that the second number does not meet a storage mode threshold; and
based at least in part on the first number meeting the charged battery threshold and the second number not meeting the storage mode threshold, place a first rechargeable battery pack of the plurality of rechargeable battery packs removably coupled to a respective battery connector in the storage mode.
